(19) United States
(12) Patent Application Publication
(10) Pub. No.: US 2024/0234547 A1
(43) Pub. Date: Jul. 11, 2024

(54) METHOD FOR PRODUCING A FIELD-EFFECT TRANSISTOR

(71) Applicant: Robert Bosch GmbH, Stuttgart (DE)

(72) Inventors: Jens Baringhaus, Sindelfingen (DE); Klaus Heyers, Reutlingen (DE)

(21) Appl. No.: 18/403,990

(22) Filed: Jan. 4, 2024

(30) Foreign Application Priority Data
Jan. 10, 2023 (DE) 10 2023 200 117.9

(51) Int. Cl. H01L 29/66; H01L 21/8234; H01L 27/088; H01L 29/423; H01L 29/78

(52) U.S. Cl. CPC H01L 29/66734; H01L 21/823431; H01L 27/0886; H01L 29/4236; H01L 29/66795; H01L 29/7813; H01L 29/785

(57) ABSTRACT

A method for producing a field-effect transistor. The method includes: providing a starting material including: a plurality of gate trenches, wherein a fin is formed between respectively two gate trenches; modifying at least a part of a surface layer of the starting material, wherein the part of the surface layer includes side surface layers on side surfaces of the fins, which side surfaces face the gate trenches, in order to obtain a modified surface layer; and at least partially removing at least a part of the modified surface layer in such a way that a width of the fins is reduced.

### FIELD

The present invention relates to a method for producing a field-effect transistor, in particular a so-called trench MOSFET, and to such a field-effect transistor.

### BACKGROUND INFORMATION

Field-effect transistors, in particular so-called MOSFETs, are used in various fields. A variant of this are so-called trench MOSFETs or T-MOSFETs, in which one channel is vertical. In this case, for example, an n-doped source layer and a channel layer located between this source layer and one of the n-doped drift layers are interrupted by trenches; gate electrodes are then arranged in such trenches.

### SUMMARY

According to the present invention, a method for producing a field-effect transistor, and a field-effect transistor are provided. Advantageous example embodiments of the present invention are disclosed herein.

The present invention relates to field-effect transistors, in particular with trenches, and their production. Different types of doping, specifically n-doping and p-doping, are used with semiconductor materials, wherein different components can be doped differently. For the sake of clarity, field-effect transistors are to be described below with a specific type of doping; n-doping is intended to be a doping of a first type, p-doping is intended to be a doping of a second type. However, it is understood that n-doping and p-doping can also be interchanged; i.e., the n-doping could be the second type of doping and the p-doping could be the first type of doping.

A field-effect transistor typically has an n-doped source layer and an n-doped drain layer (in particular comprising an n-doped drift layer, for example, applied as a so-called epitaxy layer or epitaxial layer). It also has a channel layer located vertically between the n-doped source layer and the n-doped drain layer. The channel layer can be p-doped. Furthermore, such a field-effect transistor has a plurality of gate trenches that extend vertically from the n-doped source layer to the n-doped drain layer and border on the channel layer, i.e., in particular also pass through the channel layer.

Furthermore, the field-effect transistor can have gate electrodes arranged in the gate trench, which are at least partially surrounded by a dielectric (for example, a so-called gate oxide), in particular in such a way that the gate electrode is insulated from the n-doped source layer, the channel layer and the n-doped drain layer. The gate electrode can be designed as one piece or can also be divided into at least two parts, specifically in such a way that a region of a bottom of the gate trench remains free. For example, a p-doped shielding region can be formed vertically below the gate trench, and thus in the n-doped drain layer.

A projection, a so-called fin, is formed or present between respectively two gate trenches. This is also referred to as a FinFET or a FinMOSFET.

It should be mentioned that such a field-effect transistor typically has a large number of such gate trenches and gate electrodes, and then also fins, for which the same applies as explained above, and is to be explained further. It is understood that, in addition to the gate electrodes, such a field-effect transistor also has source and drain connections, which can be formed in a conventional manner. This is a particular advantage of a trench MOSFET, since the vertical arrangement means that many gate electrodes can be arranged next to one another. In particular, the field-effect transistor can be designed as a SiC or GaN field-effect transistor; i.e., a substrate and/or generally used semiconductor material can be silicon carbide (SiC) or gallium nitride (GaN). However, semiconductor materials having an ultra-wide band gap, for example gallium oxide, can also be considered.

By selecting the appropriate geometry, epitaxial layer and implanted or used dopings, a switch-on resistance, threshold voltage, short-circuit resistance, oxide load and breakdown voltage in such a field-effect transistor can be optimized.

Such a field-effect transistor can be used alone or together with others, for example as a power switch. Preferred fields of application are, for example, in an electric drive train of a vehicle, for example in a current transformer (DC/DC converter, inverter), in charging devices for electrically powered vehicles or in solar inverters.

A FinFET or FinMOSFET is based on the depletion of the narrow, typically n-doped, fins (semiconductor fins). As a rule, the width of the fins in this case must be selected to be narrow enough that the entire fin can in each case be depleted by the overlapping depletion zones that form on the side walls or side surfaces of the fins at the MOS interface, thus forming a switchable channel region. In the case of silicon carbide, for example, thermal oxidation of the surface can be used to produce such fins. A structurally wide fin can be converted into a fin of a smaller width by thermal oxidation.

However, thermal oxidation for the production of fin structures requires long process times due to the low oxidation rates in silicon carbide. In the case of thermal oxidation, there is also a risk of the formation of carbon clusters on the surface due to excess carbon. In other materials, thermal oxidation is sometimes not applicable at all, since the oxidation rates are too low (for example, gallium nitride) or the material itself is already an oxide (gallium oxide).

It has been found that this problem can be solved by initially modifying a starting material for the field-effect transistor and then removing parts of the material. In particular, according to an example embodiment of the present invention, the starting material, which has a plurality of gate trenches, is initially provided for this purpose, wherein a fin is formed between respectively two gate trenches. The formation of the gate trenches can take place in the usual way. For example, the fins initially have a relatively large width equal to or greater than 500 nm. This can be referred to as the so-called structuring of the fins.

In the next step, a modification of at least a part of a surface layer of the starting material then takes place. This part of the surface layer comprises side surface layers on side surfaces of the fins, which side surfaces face the gate trenches. The side surface layers of the fins can also be referred to as the side walls of the fins. In addition, this part (which is modified) can also comprise bottoms of the gate trenches.

In this step, a modified surface layer is obtained. The idea here is that the starting material (semiconductor material) in the modified region can be removed as selectively as possible at a defined depth in a subsequent process step.

In a subsequent step, an at least partial removal of at least a part of the modified surface layer then follows in such a way that a width of the fins is reduced, in particular to a width of 300 nm or less. Since the resistance or resilience of the material in question is reduced during the modification, particularly in relation to the remaining material, this part can be removed particularly easily and precisely in the subsequent step.

In one exemplary embodiment of the present invention, the modification of at least the part of the surface layer comprises carrying out an ion implantation. In another exemplary embodiment, the modification comprises creating a porosity in at least the part of the surface layer. It is also possible to combine the two.

By means of the ion implantation, for example, an increase in the electrical conductivity and/or the amorphization of the semiconductor material is achieved. The porosity can be created, for example, by photochemical and/or photoelectrochemical etching.

According to an example embodiment of the present invention, etching can be used for the subsequent removal, in particular wet-chemical etching, photochemical etching or etching in hot gas media such as hydrogen and/or chlorine. Combinations of the different types of etching are also possible.

What all variants of the present invention have in common is that the modification initially significantly reduces the resistance of the surface layer in question with regard to subsequent removal, for example etching, compared to the rest of the semiconductor surface. Therefore, this surface layer can be removed at a higher rate or even selectively.

According to an example embodiment of the present invention, modification variants that break up the crystalline structure of the semiconductor as much as possible (i.e., amorphize it) are particularly preferred. Additional porosity also allows the subsequent etching medium particularly effective access to deeper layers of the semiconductor material.

In both the use of ion implantation as well as the creation of a porosity and subsequent removal, a crystal plane is preferably prepared after removal of the material, since crystal planes have an increased resistance to amorphization and porosity creation.

In the process according to the present invention described, methods can be used, for example, in which basically the entire surface of the starting material is modified and/or removed. This can lead to undesirable, excessive removal of the fin tip, i.e., the upper side of the fin (narrow side), which can have a detrimental effect on subsequent contacting of the fin at this location. For this reason, it is particularly useful to protect the tip or upper side of the fin by means of suitable masking. Thus, a mask is preferably applied to the upper sides of the fins prior to modification, which mask in particular is only removed again after the at least partial removal of at least the part of the modified surface layer. Advantageously, the masking is directly part of a mask that was used for the initial structuring of the fins. This means that the mask on the upper side of the fins can also already be applied to the provided starting material.

In the further course, the gate electrodes can be inserted into the gate trenches. At least one, but also all gate electrodes, can be divided into at least two parts in such a way that a region of a bottom of the relevant gate trench remains free during insertion. Thereafter, the field-effect transistor can be metallized.

It is understood that further steps may be necessary for the final field-effect transistor, such as edge finishing and contact path implementation and the like; conventional methods can be used in this case. However, the steps described above relate in particular to the so-called cell field of the field-effect transistor, in which the gate trenches are formed.

Further advantages and embodiments of the present invention can be found in the description and the figures.

The present invention is shown schematically in the figures on the basis of exemplary embodiments and is described below with reference to the figures.

### BRIEF DESCRIPTION OF THE DRAWINGS

FIG. 1 schematically shows a field-effect transistor according to the present invention in a preferred embodiment.

FIG. 2 schematically shows a sequence of a method according to the present invention in a preferred embodiment.

FIG. 3 schematically shows a sequence of a method according to the present invention in a further preferred embodiment.

### DETAILED DESCRIPTION OF EXAMPLE EMBODIMENTS

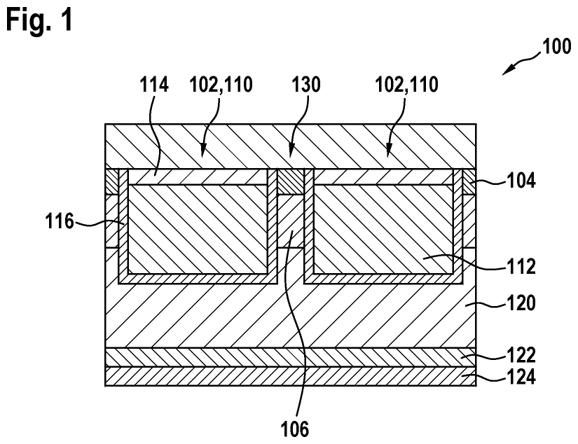

FIG. 1 shows, schematically and by way of example, a field-effect transistor 100 according to the present invention in a preferred embodiment, namely a so-called trench MOSFET as a so-called FinMOSFET. In particular, silicon carbide (SiC), gallium nitride (GaN) or gallium oxide can be used as the semiconductor material; these semiconductor materials have a wide to very wide band gap.

The field-effect transistor 100 has an n-doped source layer 104, an n-doped drain layer comprising an n-doped drift layer or a so-called epitaxy layer 120, and a channel layer 106 located vertically (seen here from top to bottom) between the n-doped source layer 104 and the n-doped drain layer. Optionally, an n-doped spread layer located vertically between the channel layer 106 and the n-doped drift layer 120 can be comprised by the n-doped drain layer, which has a higher n-doping than the n-doped drift layer 120.

Furthermore, the field-effect transistor 100 has a plurality of gate electrodes 110 which are inserted into one of a plurality of gate trenches 102 in each case. The gate electrodes 110 each have an insulating oxide 114 and a dielectric or a gate oxide 116 that surrounds a gate semiconductor material 112. The gate electrode is at least adjacent to the channel layer 106 via the dielectric 116. The gate electrodes are used to control a channel region in the channel layer 106. In each case, a channel is formed in a region of the channel layer 106 that is adjacent to the gate trench or a gate electrode. The gate electrodes are typically guided within the gate trenches to the end of the trenches (i.e., the end of the cell field) and are guided out of the trenches at this location and contacted, or are contacted directly at this location.

Between respectively two of the gate trenches, and therefore also between respectively two of the gate electrodes, there is in each case a projection or a so-called fin 130. These fins 130 are used as the channel layer 106 or are designed as such.

Furthermore, the field-effect transistor 100 has an n-doped substrate 122 adjacent to the bottom of the n-doped drift layer 120 and a drain material 124, such as a metal, adjacent to the bottom of the n-doped substrate 122.

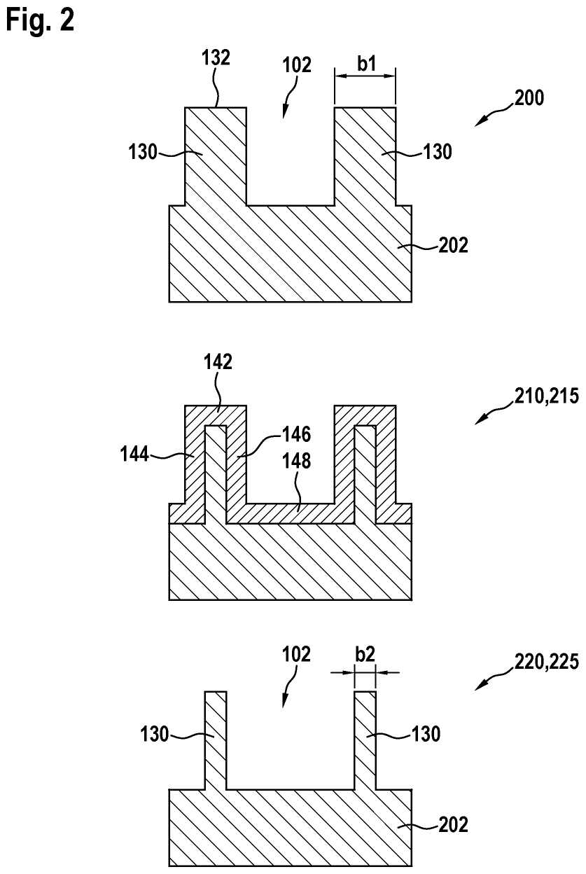

FIG. 2 shows, schematically and by way of example, a sequence of a method according to the present invention in a preferred embodiment. In each case, illustrations are shown for various, but not all, steps. In particular, a field-effect transistor such as the field-effect transistor 100 from FIG. 1 can be produced in this case.

In one step 200, a starting material 202 is provided, which has a plurality of gate trenches 102, wherein a fin 130 is formed between respectively two gate trenches. The fins have a width with a value b1, which can be 500 nm or more, for example. The specific layers in the starting material, as explained with reference to FIG. 1, are not (yet) important here; these can, for example, be created later, for example by suitable doping.

In order to form the gate trenches or the fins, for example, a suitable mask can be applied to a substrate, so that etching can take place in the intermediate spaces thereof in order to obtain the starting material 202 shown here.

In one step 210, a modification of at least a part of a surface layer of the starting material then takes place. This surface layer can be the entire layer located on a surface on the upper side of the starting material 202, for example up to a certain depth. By way of example, this surface layer is shown hatched and comprises side surface layers 144, 146 on side surfaces of the fins 130, which side surfaces face the gate trenches 102, upper-side surface layers 142 on the upper sides 132 of the fins, and bottom surface layers 148 on bottoms of the gate trenches 102. This results in a modified surface layer.

The modification 210 can comprise, for example, creating 215 a porosity in at least the part of the surface layer; in the example shown, the entire surface layer is modified. This significantly reduces the resistance of the surface layer compared to the rest of the starting material 202.

In one step 220, the modified surface layer or at least a part thereof is then removed, at least partially, but preferably completely. This can take place by etching 225. In particular, only or at least substantially only the modified surface layer is removed, since this is already modified, i.e., for example, is porous. By contrast, the significantly more resistant remaining regions of the starting material are not etched away, or at most are barely etched away.

Thus, the plurality of gate trenches 102 are finally formed, wherein the fins are narrowed in each case, i.e., their width is reduced, in this case to a value b2 of, for example, 300 nm or less.

Further steps can follow in order to complete the field-effect transistor, such as inserting the gate electrodes, forming contacts and metallization, for example as the application of drain and source material as shown in FIG. 1.

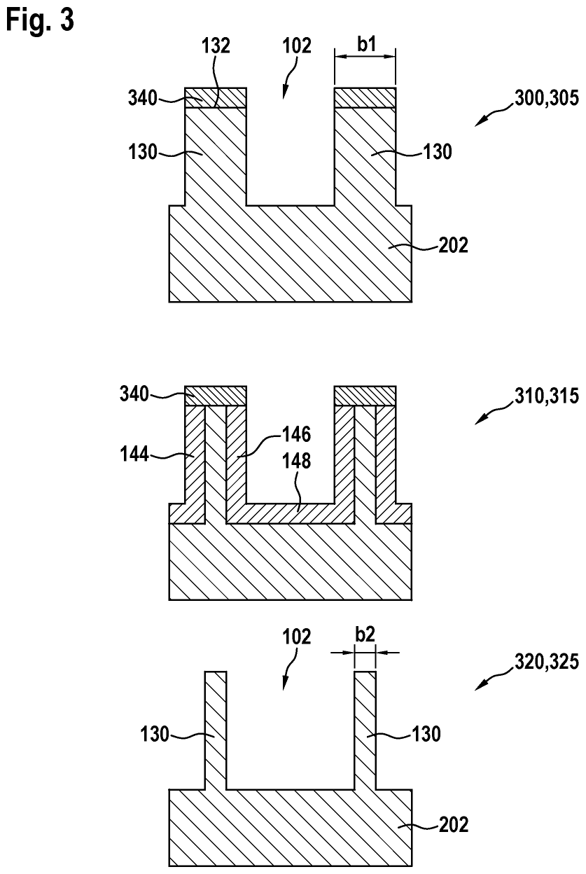

FIG. 3 shows, schematically and by way of example, a sequence of a method according to the present invention in a further preferred embodiment. In each case, illustrations are shown for various, but not all, steps. In particular, a field-effect transistor such as the field-effect transistor 100 of FIG. 1 can be produced in this case.

In one step 300, a starting material 302 is provided, which has a plurality of gate trenches 102, wherein a fin 130 is formed between respectively two gate trenches. The fins have a width with a value b1, which can be 500 nm or more, for example. The specific layers in the starting material, as explained with reference to FIG. 1, are not (yet) important here; these can, for example, be created later, for example by suitable doping.

In order to form the gate trenches or the fins, for example, a suitable mask can be applied to a substrate, so that etching can take place in the intermediate spaces thereof in order to obtain the starting material 302 shown here. This mask can also comprise, for example, the mask 230 which is applied to the upper sides 132 of the fins and also initially remains applied. It is also possible that the mask 340 is applied in a step 305 after the formation of the gate trenches or fins.

In one step 310, a modification of at least a part of a surface layer of the starting material then takes place. This surface layer can be the entire layer located on a surface on the upper side of the starting material 202, for example up to a certain depth. By way of example, this surface layer is shown hatched and comprises side surface layers 144, 146 on side surfaces of the fins 130, which side surfaces face the gate trenches 102, and bottom surface layers 148 on bottoms of the gate trenches 102. This results in a modified surface layer.

Any surface layers on the upper sides 132 of the fins are not modified here, unlike the upper side surface layers 142 in the example in FIG. 2, since the mask 340 is applied.

The modification 310 can comprise, for example, creating 315 a porosity in at least the part of the surface layer; in the example shown, the entire surface layer is modified. This significantly reduces the resistance of the surface layer compared to the rest of the starting material 202.

In one step 320, the modified surface layer or at least a part thereof is then removed, at least partially, but preferably completely. This can take place by etching 325. In particular, only or at least substantially only the modified surface layer is removed, since this is already modified, i.e., for example, is porous. By contrast, the significantly more resistant remaining regions of the starting material are not etched away, or at most are barely etched away.

The mask 340 can then be removed again. Thus, the plurality of gate trenches 102 are finally formed, wherein the fins are narrowed in each case, i.e., their width is reduced, in this case to a value b2 of, for example, 300 nm or less.

Further steps can follow in order to complete the field-effect transistor, such as inserting the gate electrodes, forming contacts and metallization, for example as the application of drain and source material as shown in FIG. 1.

1-12. (canceled)

13. A method for producing a field-effect transistor, comprising the following steps:
providing a starting material including: a plurality of gate trenches, wherein a fin is formed between respectively each two of the gate trenches;
modifying at least a part of a surface layer of the starting material, wherein the part of the surface layer includes side surface layers on side surfaces of the fins, the side surfaces face the gate trenches, to obtain a modified surface layer; and
at least partially removing at least part of the modified surface layer in such a way that a width of the fins is reduced.

14. The method according to claim 13, wherein the modifying of at least the part of the surface layer includes carrying out an ion implantation.

15. The method according to claim 13, wherein the modifying of at least the part of the surface layer includes creating a porosity in at least the part of the surface layer.

16. The method according to claim 15, wherein the creating of the porosity in at least the part of the surface layer takes place by etching, the etching including photochemical etching and/or photoelectrochemical etching.

17. The method according to claim 13, wherein the at least partial removal of at least the part of the modified surface layer takes place by etching.

18. The method according to claim 17, wherein the etching for at least partially removing at least the part of the modified surface layer includines wet-chemical etching and/or photoelectrochemical etching and/or etching in a hot gas medium.

19. The method according to claim 13, wherein a mask has been or is applied to upper sides of the fins prior to the modification, and wherein the mask is removed only after the at least partial removal of at least the part of the modified surface layer.

20. The method according to claim 13, wherein the width of the fins is reduced to a value equal to or less than 300 nm by the at least partial removal of at least the part of the modified surface layer.

21. The method according to claim 13, wherein the width of the fins prior to the modification is a value equal to or greater than 30 nm.

22. The method according to claim 13, wherein a SiC or GaN or gallium oxide field-effect transistor is produced as the field-effect transistor.

23. The method according to claim 13, wherein the fins are formed as a channel layer.

24. A field-effect transistor, the field-effect transistor having be produced by:
providing a starting material including: a plurality of gate trenches, wherein a fin is formed between respectively each two of the gate trenches;
modifying at least a part of a surface layer of the starting material, wherein the part of the surface layer includes side surface layers on side surfaces of the fins, the side surfaces face the gate trenches, to obtain a modified surface layer; and
at least partially removing at least part of the modified surface layer in such a way that a width of the fins is reduced;
wherein gate electrodes are arranged in the gate trenches.
